(19) United States
(12) Patent Application Publication
(10) Pub. No.: US 2024/0251523 A1
(43) Pub. Date: Jul. 25, 2024

(54) HEAT EXCHANGER FOR HIGH PERFORMANCE CHIP SETS

(71) Applicant: Mikros Technologies, Inc., Claremont, NH (US)

(72) Inventors: Drew M. Matter, Hanover, NH (US); Jesse D. McGowan, Alexandria, NH (US); Joseph T. Sullivan, Hanover, NH (US); Javier A. Valenzuela, Naples, FL (US)

(21) Appl. No.: 18/420,324

(22) Filed: Jan. 23, 2024

Related U.S. Application Data
(60) Provisional application No. 63/440,682, filed on Jan. 23, 2023.

(51) Int. Cl. H05K 7/20

(52) U.S. Cl. CPC H05K 7/20254; H05K 7/20272; H05K 7/20772

(57) ABSTRACT

Presently disclosed is a cold plate heat exchanger with reduced thermal resistance for use with high-performance computing chips sets used in high power density servers. The improved reduced thermal resistance cold plate includes a thin, microchannel cold plate that is pressed against a heat generating device using an elastomeric element to elastically flex the cold plate so that it conforms to the surface of the heat generating device, thereby minimizing the thermal resistance of the interface between the two.

### RELATED APPLICATIONS

This disclosure claims priority to and benefit of U.S. Provisional Patent Application No. 63/440,682, entitled “Heat Exchanger for High Performance Chips Sets,” filed on Jan. 23, 2023, the contents of which are incorporated herein by reference.

### TECHNICAL FIELD

This disclosure relates generally to a cold plate heat exchanger with reduced thermal resistance for use with high-performance computing chips sets used in data centers to reduce energy consumption.

### BACKGROUND

The use of heat exchangers for cooling of computer hardware is known in the art. As technology in the semiconductor industry continues to advance, so too does the need for improved cooling solutions. For example, state-of-the art graphics processing units such as the H100 GPU by NVIDIA features 80 billion transistors and two types of cores that are designed to be up to 9× faster than its predecessors.

Semiconductor devices in data centers or supercomputers generate a significant amount of heat during operation and require cooling. The transistors and active components on the silicon of the CPU/GPU consumes a significant amount of electricity, which is dissipated as heat, and requires active cooling to keep the silicon maximum temperature below their rated maximum temperature, generally between about 80 and 95 C. Above these critical temperatures, the silicon chips begin to malfunction, so effective cooling is needed to ensure the proper operation of a high performance computing cluster in a data center or supercomputer.

The U.S. Department of Energy (DOE) recognizing the need to overcome technology barriers associated with the development of high-performance energy efficient cooling solutions for data centers has announced up to $42 million in funding to find a resolution to the problem. According to the DOE data centers that are used to house computers, storage systems and computing infrastructure, account for approximately 2% of total U.S. electricity production while data center cooling can account for up to 40% of data center energy usage overall. Reducing the amount of energy data centers use for cooling will help to lower the operational carbon footprint associated with powering and cooling data centers and help companies and countries reach worldwide sustainability goals.

The most common form of cooling today in data centers utilizes air as the coolant. Cold air is forced through a cooling device, known as a heat sink, by a fan and heats up as it removes the heat. This hot air is then cooled by a heat rejection device that removes the heat from the air and rejects it to the atmosphere outside the data center; these heat rejection devices can be, for example, a radiator, a water-cooling tower, a compressor/chiller, or similar device. The heat sink which attaches to the CPU/GPU is made of a conductive material, for example aluminum or copper, and has fins that stretch away from the CPU/GPU surface. These fins increase the surface area over which the device can transfer heat into the air and improve the heat rejection performance. These heat sinks are attached to the silicon using a thermal interface material (generally a thermally conductive grease or thermally-conductive compliant pad), that creates a low-resistance thermal bond between the silicon and the heat sink. These thermal interface materials are used because the surface of both the silicon and heat sink are not perfectly flat, and air gaps between the two devices would lead to incredibly large thermal resistances, and poor cooling performance.

Prior art microchannel cold plates are rigid and do not significantly deform under the loads that can be safely applied to electronic components (20-40 psi). Some prior art cold plates are brazed to a metal manifold that distributes the coolant, thus making it rigid because of the manifold's thickness. Other prior art cold plates utilize parallel flow channels and the matrix thickness needs to be large (several mm) to reduce the pressure drop. The fins are fabricated on a metal base that is several mm thick. The tall fins and thick base result in a rigid cold plate.

Supercomputers or data centers which require more high frequency and complex calculations, often referred to as “high performance computing,” cannot be effectively cooled by air, as the heat loads in the CPU/GPUs are much higher than in a traditional data center. For these applications, liquid coolants are used to remove the heat directly from the CPU/GPU. Conventionally, a water block or cold plate is mounted directly to the CPU/GPU into which cold water is pumped and hot water exits. The hot water is then cooled back down by a heat rejection device which dissipates that heat to the outside ambient air (see above for examples).

In such devices, the cold plate consists of either fins or channels that are internal to the cold plate and are optimized to efficiently remove heat from the CPU/GPU. The cold plate is mounted and pushed on to the CPU/GPU with a thermal interface material (or “TIM”) in between to improve the performance and fill in potential air gaps between the cold plate and the CPU/GPU. Generally, the cost of the cold plates is higher than heat sinks used with air cooling, so liquid cooling is reserved for the CPU/GPUs, which are the highest heat output devices on a server, and thus have the highest cooling requirements. Air cooling is often used in parallel to cool the low power devices on the board, which commonly adds significant complexity to a cooling system for a data center, as parallel cooling systems for liquid and air are needed.

To address this complexity of running air and liquid cooling loops in parallel, many data centers are now using immersion liquid cooling for their high-performance computing needs. In these systems, the entire board is submerged in a dielectric fluid that is recirculated in a bath, and its sensible heat is rejected to the outside ambient air by one of the heat rejection devices mentioned above. The dielectric coolant is by nature non-conductive, so the CPU/GPUs and electronic devices are not shorted or impacted in their function in any way. Any number of known dielectric coolants may be utilized. The advantage of this approach is that low power devices (such as memory) are readily cooled and expensive heat sinks can be eliminated as the thermal properties of liquid dielectric coolant are significantly better than air. For cooling the CPU/GPU, which has a higher heat load per area, a heat sink or cold plate can be effectively used to increase the surface area for heat transfer; this heat sink may also be attached via a thermal interface material.

The above options are currently deployed in HPC data centers with varied success on the current generation of CPU/GPUs. However, two factors make the above cooling technologies insufficient for tomorrow's needs. First, CPU/GPUs will generate significantly more heat, increasing the demands on the cooling system's performance. Second, data centers are required to be more energy efficient and new guidelines require the cooling system to move more heat while using less electrical power to do so. These two compounding factors mean that cooling systems of the future will need to reduce the thermal resistance or improve their cooling performance to meet this need.

### SUMMARY

Presently disclosed is a cold plate heat exchanger with reduced thermal resistance for use with high-performance computing chips sets used in high power density servers.

Although Immersion cooling has been shown to provide large scale energy savings with low-power components in large scale computing systems, high heat-flux components—those emitted high thermal power per unit area (W/cm2)—remain difficult to cool with conventional cooling designs, due to the inherent lower surface area available for direct cooling.

The cold plates of the present disclosure provide highly effective, high cooling capacity (W/C-cm2) thermal management for large area, high power processors and can be integrated into immersion cooling systems into which they may be submerged. The thermal interface materials can be eliminated, thus significantly reducing the thermal resistance in the cooling system.

The improved reduced thermal resistance cold plate disclosed herein includes a thin, microchannel cold plate that is pressed against a heat generating device using an elastomeric element to elastically flex the cold plate so that it conforms to the surface of the heat generating device, thereby minimizing the thermal resistance of the interface between the two.

In one embodiment, the load required to deform the microchannel cold plate is produced by compressing the elastomeric element. In another embodiment, the load is generated by adjusting the pressure of the cooling fluid. The thermal resistance of the interface may be reduced further by supplying a low viscosity fluid to the interface.

In one embodiment, an interconnected network of microgrooves is fabricated on the surface of the microchannel cold plate to supply the low viscosity fluid and vent any fluid trapped at the interface. In another embodiment, the microchannels are fluidically connected to the heat acquisition face of the microchannel cold plate and allow the cooling fluid to fill the interface.

### FIGURES

The foregoing features may be more fully understood from the following description of the drawings. Various aspects of at least one embodiment are discussed below with reference to the accompanying figures, which are not necessarily drawn to scale, emphasis instead being placed upon illustrating the principles disclosed herein.

The drawings aid in explaining and understanding the disclosed technology. Since it is often impractical or impossible to illustrate and describe every possible embodiment, the provided figures depict one or more exemplary embodiments. The figures are incorporated in and constitute a part of this specification but are not intended as a definition of the limits of any embodiment.

Accordingly, the figures are not intended to limit the scope of the invention.

Like numbers in the figures denote like elements. For simplicity, not every component may be labeled in every figure.

FIG. 1 is a side view of the flexible cold plate assembly according to the present disclosure;

FIG. 1A is a side view of the flexible cold plate assembly in operation with a heat generating device having a convex surface;

FIG. 1B is a side view of the flexible cold plate assembly ii operation with a heat generating device having a concave surface;

FIG. 2 is a side view of the flexible cold plate assembly in operation with load generation by compression of elastomeric manifold;

FIG. 2A is a side view of the flexible cold plate assembly in operation with load generation by control of coolant pressure;

FIG. 3 is a fluid flow diagram according to the present disclosure with a closed face normal flow microchannel matrix;

FIG. 3A. is a fluid flow diagram according to the present disclosure with an open face normal flow microchannel matrix;

FIG. 4 is a perspective view of the flexible cold plate assembly according to the present disclosure;

FIG. 5 is an exploded view of FIG. 4;

FIG. 6 is a side perspective view of the flexible cold plate assembly with an open face microchannel matrix;

FIG. 7 is an exploded view of FIG. 6;

FIG. 8 is a side view of the flexible microchannel matrix in operation adapted for discontinuity on heat generation surface curvature; and

FIG. 9 is an exploded view of FIG. 6, with a bottom perspective view of the flexible microchannel matrices.

### DETAILED DESCRIPTION

The present disclosure will hereinafter be described with respect to one or more exemplary embodiments, with the understanding that the present disclosure is to be considered an exemplification and is not intended to limit the invention to the specific embodiments illustrated. It will be understood to one of skill in the art that the apparatus, system and/or method is capable of implementation in other embodiments and of being practiced or carried out in various ways. Also, the phraseology and terminology used herein is for the purpose of description and should not be regarded as limiting. Any references to examples, embodiments, components, elements or acts herein referred to in the singular may also embrace embodiments including a plurality, and any references in plural to any embodiment, component, element, or act herein may also embrace embodiments including only a singularity (or unitary structure). References in the singular or plural form are not intended to limit the presently disclosed apparatus, system and/or method, their components, acts, or elements. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. The use of the term “and” may be construed to include additional items or used as to describe alternative items.

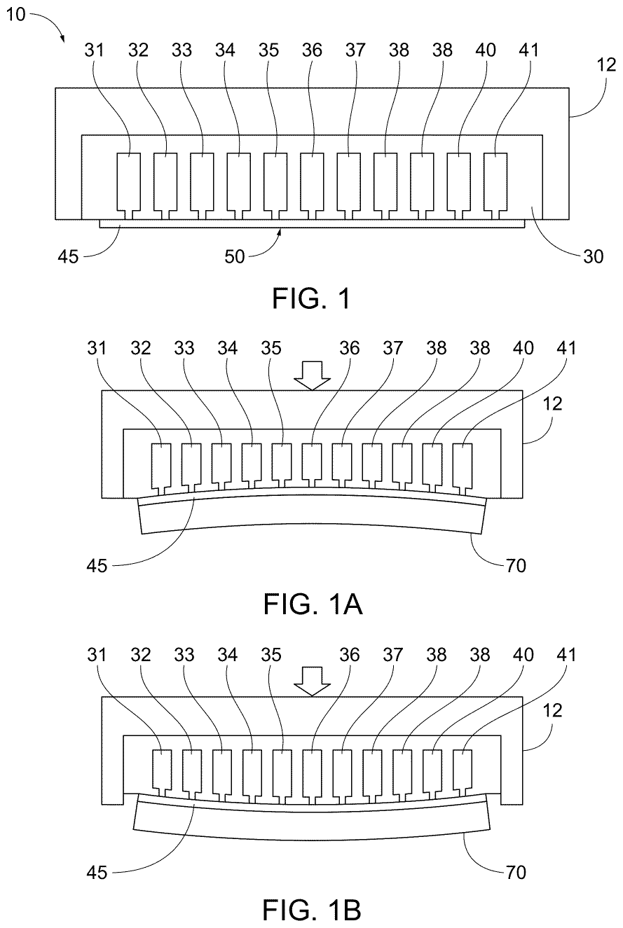

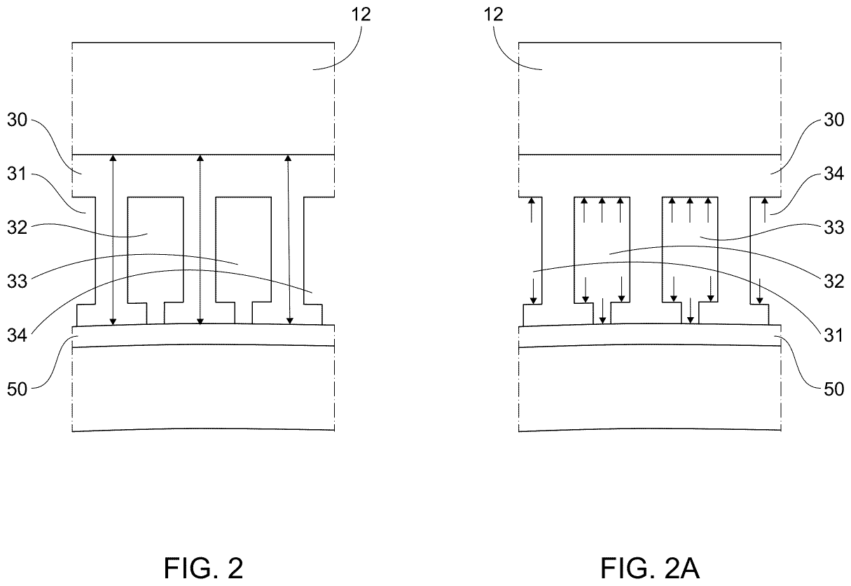

Referring initially to exemplary FIGS. 1 and 2, a thin heat transfer matrix may be fabricated using the microchannel geometries and fabrication methods described in, for example, U.S. Pat. No. 8,474,516 owned by the current applicant, which is incorporated herein by reference. Using these geometries, the matrix thickness is between approximately 5 to 7 times the microchannel size to achieve the desired thermal performance. Matrices with microchannels sizes of 150 microns or less can have a thickness of approximately 1 mm or less. Moreover, the heat transfer matrices have high void fraction, with microchannels occupying between approximately 30 to 50% of the total volume of the cold plate material. The high void fraction reduces the effective modulus of elasticity of matrix. The thin geometry and lower modulus make the matrix flexible.

The flexible matrix 50 is attached to a compliant manifold 30 fabricated out of a suitable elastomeric material (e.g. Silicone) that can bend and/or deform elastically as shown for example in FIG. 1. The manifold has a plurality of channels 31, 32, 33, 34, 35, 36, 37, 38, 39, 40, 42 to supply and collect fluid from the matrix. A rigid housing 12 encloses the back and sides of the manifold as shown in the drawings.

During operation the flexible cold plate assembly 10 is pressed against the heat generating surface 70 using a suitable mounting force. The mounting force is distributed by the compliant manifold 30 to the back face 45 of the flexible matrix 50 and the flexible matrix 50 deforms to match the curvature of the heat generating surface 70. Because of varying thermal stresses, the shape of the heat generating surface can vary from concave to convex during operation. The distributed force on the back face 45 of the matrix causes the curvature of the matrix to follow the changes in curvature of the heat generating surface. The load applied to the back side 45 of the matrix 50 to achieve the required deformation results from a combination of the elastic compression of the manifold material and the cooling fluid pressure. Depending on the application, it may be advantageous to rely on one or the other method to control the magnitude of the load.

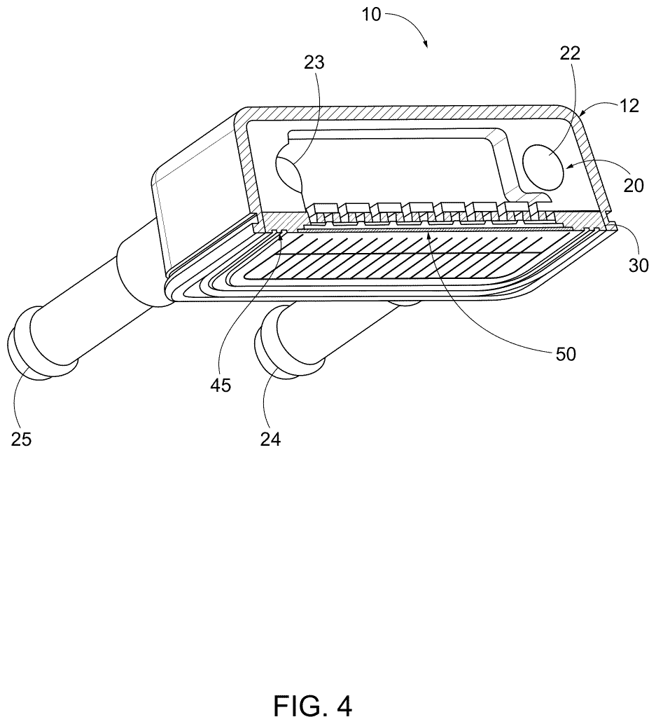

Three exemplary embodiments are illustrated in FIGS. 4 ,6, and 9. In the first embodiment shown in FIG. 4, the matrix 50 is bonded to thin copper foil 47 that is sealed to the edge of the housing, for example by hermetical sealing. The foil may include corrugations in the space between the matrix and the housing to provide compliance between the housing and the matrix. A hierarchical network of grooves is fabricated on the outer face of the foil to facilitate squeezing out the TIM during installation. The thin compliant manifold 30 bridges the gap between the matrix 50 and the rigid header 12. This embodiment is intended for application employing aqueous coolants (EG or PG water mixtures) that require leak tight cold plates. Preferably, a low viscosity, high thermal conductivity would be used as the TIM. In one exemplary embodiment, the load required to make the matrix conform to the die would be generated by controlling the coolant pressure inside the manifold. The matrix could be formed in a convex manner to make contact in the central portion of the silicon first, pushing the TIM to the outer perimeter to inhibit air pocket voids that can increase thermal resistance.

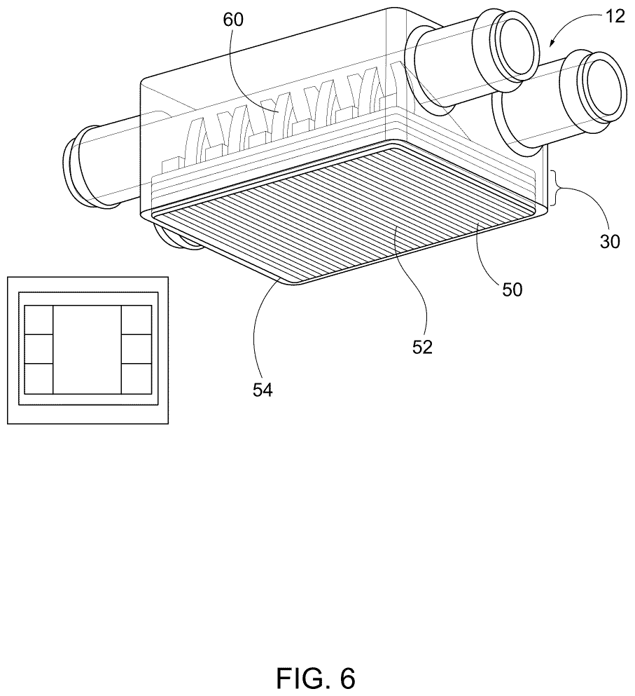

The second exemplary embodiment (FIG. 6) is intended for use in immersion cooling systems. In such systems, all the electronic components are immersed in a circulating dielectric bath. In the immersed cooling application, the cold plate 10 does not need to be leak tight, and that allows greater freedom in the implementation of the flexible matrix cold plate. In this embodiment, the overall thermal resistance between the incoming coolant, and the active regions of the silicon is reduced. This is primarily done by eliminating the use of the traditional thermal interface materials that generally mate the cold plate to the silicon. Instead, the lower-most channels are open, and the liquid dielectric coolant comes in direct contact with the silicon, as described in further detail below.

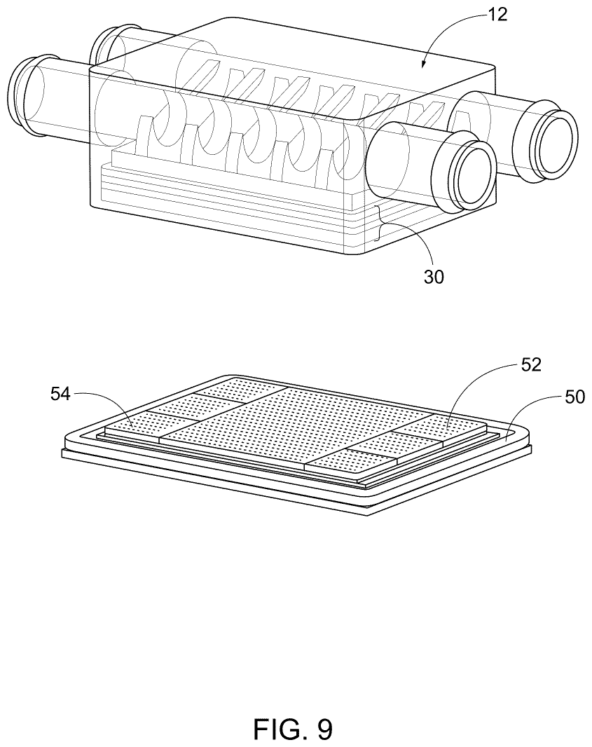

In the embodiment of FIG. 6, the exemplary microchannel matrices may be segmented so that the size of the plurality of each matrix segment 52, 54 is the same as that of the die it is cooling. This segmentation may also be referred to as “tiles.” This segmentation, if utilized, allows accommodation of the discontinuities in the curvature of the die surface observed in multichip devices, as Illustrated in FIG. 9. Because the silicon wafer may bow or curve during operation, the copper cold plate 45 is also flexible to conform to the surface topology of the silicon. As such the copper portion of the cold plate may be both thin (<1 mm) and/or segmented into tiles 52,54 to allow it to bend and conform to the die shape.

The plurality of tiles of copper 52,54 that contain fluidic channels can each be tailored to the heat flux or power dissipation for different regions of the silicon chip. In many silicon dies, the heat output varies as a function of position. This is especially true for multi-chip modules, where memory units are placed next to the die; these locations have lower cooling requirements. Using copper “tiles” 52,54 with embedded fluidic channels enables each one to be tailored for pressure drop and performance. In some cases, a group of tiles that are similarly tailored can be positioned together in the same zone. For example, in one non-limiting embodiment, tiles placed in a first zone above the memory chips would have a higher pressure drop than the ones placed in a second zone above the CPU/GPU where most of the heat is generated, and all the “tiles” would receive coolant in parallel. This would ensure that the majority of the flow will go into the CPU/GPU, and a reduced amount of coolant is provided to the memory chips which have reduced cooling requirements; which ensures that the coolant flow rate is kept at a minimum.

Additionally, the tiled approach will allow the copper channels to conform overstep changes in height on multi-chip modules. For example, the memory chips and the CPU/GPU are often on different pieces of silicon, and there is thus a discontinuity in the surface profile between these pieces of silicon. If the tiles are separated along this boundary between the silicon chips, they can each conform to their respective silicon chips without kinks in their profile, thus ensuring intimate contact over the entire silicon's' surfaces.

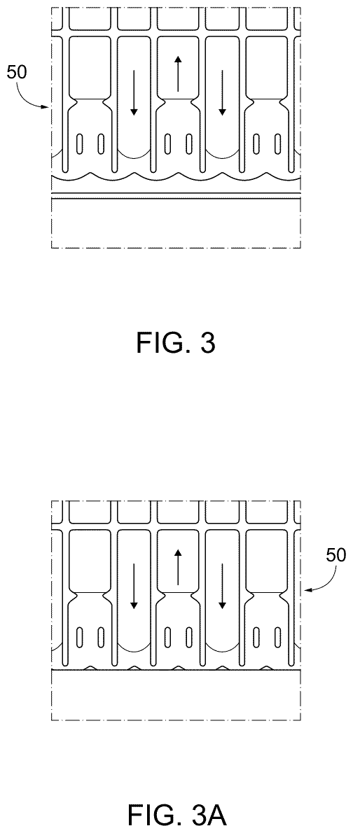

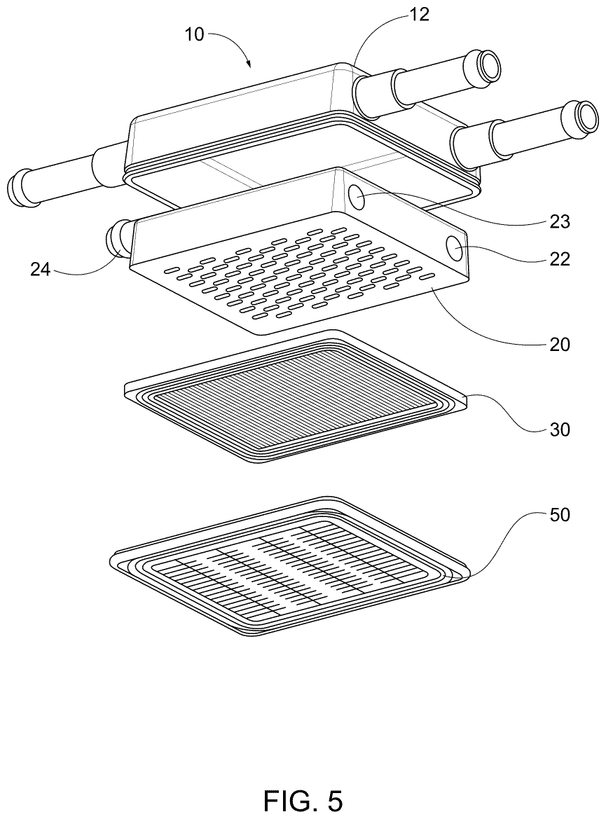

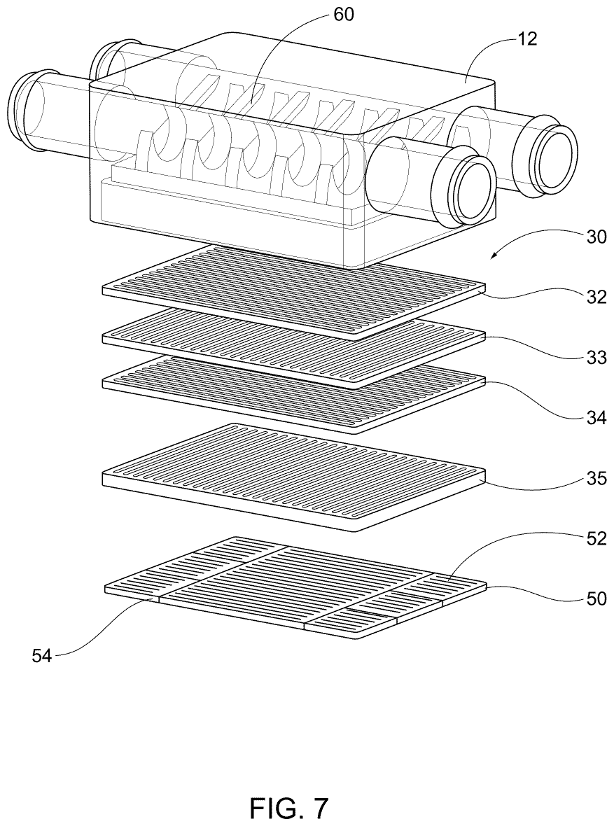

Referring again to FIG. 6 and FIG. 7, the microchannels are exposed at the bottom of the matrix and are not covered. For example, as shown in FIGS. 3, 4, and 5, the bottom of the matrix is covered by the TIM. Because the microchannels are exposed and not covered, this embodiment may also be referred to as the open microchannel matrix 50. The open microchannel matrix 50 allows direct contact and heat transfer between the coolant and the surface of the heat generating device 70. The coolant also serves as a thermal interface material filling the microscopic voids at the interface. During fabrication, the surface of the heat generating device 70 as well as that of the matrix are smoothed, for example they may be lapped and polished so that there is close contact between them when they are pressed together during operation.

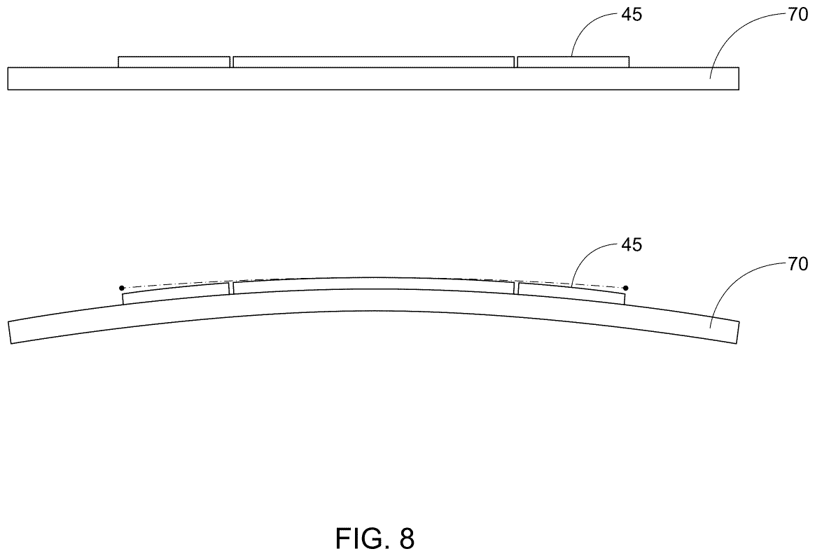

During use, a distributed pressure is applied across the matrix to allow it bend and conform to the die shape. To do this, a layered structure of different materials may be utilized in the cold plate construction. As shown in FIGS. 7 and 8, the bottom layer 50 may be made of copper, and contains fluidic channels; and is where the heat transfer is performed. The second layer is a manifold layer that is responsible for directing fluid into and out of the copper channels. This manifold layer will be both flexible and compliant. The manifold layer 30 can be comprised of a plurality of layers 32, 33, 34 and 35. In one embodiment, the manifold layer 30 may be made of either silicone or a compliant plastic and is stacked between the microchannel matrix and the third layer. The third or top layer is made of a rigid layer which is held firmly in place by the mounting hardware outboard of the CPU/GPU package. In one embodiment, this third rigid layer also contains fluidic ports for the inlet and outlet to the cold plate. This layering enables the copper surface to conform and bend to the silicon surface's shape, even as it changes during heat-up and cool-down cycles.

The virtue of being in an immersion system means that the coolant can come in direct contact with the silicon without disturbing its operation or function. Additionally, leaks in the cold plate are not a concern, as the entire system is submerged in coolant. Also, the outlet from the cold plate can simply discharge in one or many directions into the immersion bath. One of ordinary skill in the art would readily understand that the outlet(s) of the cold plate can be directly at other high-power devices that have stringent cooling requirements.

In a variation on the embodiment, the matrices could retain their bottom face (closed matrix) and a low viscosity, high thermal conductivity material could be used at the thermal interface.

A third exemplary embodiment of the flexible matrix 50 is shown in FIG. 9. This embodiment is also intended for use with a dielectric coolant. The geometry of the components may be the same or similar as that of the previous embodiment, except that the microchannel matrices are closed, and they are soldered to the die. Because the matrices are very thin and have void fractions greater than approximately 35%, their yield strength is much lower than that of the silicon dies. During cooldown from soldering temperatures the matrices will yield limiting the magnitude of the compressive the stresses on the silicon die.

In one exemplary embodiment of the flexible cold plate assembly two coolants are utilized. A dielectric coolant cools the low-power components via a recirculated immersion loop. A propylene glycol mixture cools the high power GPUs in a server using the flexible cold plate. For example, the propylene glycol mixture could be comprised of 25% propylene glycol and 75% water. The cold plates are designed and manufactured to lower the thermal resistance of the current microchannel cold plates. The methods are adapted to improve microchannel performance and enable higher surface area for convection to the propylene glycol mixture and reduce the core resistance by approximately 20%.

The internal structure of the cold plates is adapted to allow for the active surface to conform to the die shape. This allows minimization of the TIM bond line thickness between cold plate and chip case that can be a thermal resistance bottleneck in current systems. In one embodiment, the TIM bond line thickness is reduced from approximately 100 microns to 25 microns.

In another embodiment, the propylene glycol coolant loop is eliminated, and the dielectric coolant is used in the cold plate and as an immersion coolant. The improved microchannel designs are constructed and arranged to allow for very low pressure drops to enable the high flow rates required to reduce fluid thermal resistance. The new normal flow microchannel designs are adapted for use with dielectrics that will enable core resistances to meet ARPA-E target, for example. In certain embodiments, traditional TIM is eliminated, and a dielectric coolant is utilized with an extremely smooth and well-mated surface to reduce the overall interface resistance.

The elimination of the largest thermal resistance in the network i.e., the traditional TIM that is used to mate the cold plate to the silicon, achieves the target cooling objectives. In lieu of a traditional thermal interface material, the improved cold plate system utilizes microchannels that are an open construction to allow direct contact between liquid dielectric coolant and the silicon. However, impingement of coolant onto the silicon alone may not provide sufficient cooling for certain applications. Additionally, the new open channel design aids in thermally syncing the cold plate's copper channel walls to the silicon, acting as a liquid thermal interface. The copper channel walls add significant surface area for convective heat transfer from to the coolant, and greatly enhance the performance of the cold plate.

Providing an excellent thermal interface between the copper surface and the silicon is needed when using the open matrix design of FIGS. 6 and 7. To achieve the goal of an ultra-low thermal resistance, the copper walls and the silicon are brought into intimate, close contact. Due to the low thermal conductivity of most dielectric coolants, the distances here may be below a fraction of a micron. Fortunately, silicon is very smooth, with most roughness measured in nanometers. To reduce the roughness of the copper suitable for smooth contact with the silicon, the copper may be lapped and polished to ensure that the roughness is below 200 nm, or may be otherwise smoothed as would be known to those of skill in the art.

Minimizing roughness is a first step to achieve good thermal contact between the silicon and copper. Most silicon wafers are bowed or curved, which means the copper cold plate needs to be flexible to conform to the surface topology of the silicon. As such, the copper portion of the cold plate should be both thin (<1 mm) and segmented into tiles to allow it to bend and conform to the die shape during heating and cooling.

A distributed pressure may be applied across the copper to allow it bend and conform to the die shape. To do this, a layered structure of different materials may be utilized in the cold plate construction, as discussed above. The bottom layer may be made of copper and contains fluidic channels for heat transfer. The second layer is a manifold layer that is responsible for directing fluid into and out of the copper channels. This manifold layer may be both flexible and compliant. In one embodiment, the manifold layer is made of either silicone or a compliant plastic. The third layer on top is made of a rigid layer which may be pushed down by mounting hardware outboard of the GPU package. This third rigid layer may also contain fluidic ports for the inlet and outlet to the cold plate. This stack-up design enables the copper surface to conform and bend to the silicon surface's shape, even as it changes during heat-up and cool-down cycles.

Other interface options between the silicon and the copper are also envisioned, including soldering the individual tiles on the silicon die directly, or other methods as would be known to those of skill in the art. This is expected to result in a very low resistance at the copper/silicon interface but may also include an additional metallization step to the top of the silicon die. This metallization step may be needed if testing shows that the contact resistance between the silicon and the copper is higher than expected.

Having thus described several aspects of at least one disclosed example, it is to be appreciated that various alterations, modifications, and improvements will readily occur to those skilled in the art, without departing from the spirit and scope of the invention as defined by the appended claims. Therefore, the claims are not to be limited to the specific example(s) depicted herein. For example, the features of one example disclosed above can be used with the features of another example. Furthermore, various modifications and rearrangements of the parts may be made without departing from the spirit and scope of the underlying inventive concept. Such alterations, modifications, and improvements are intended to be part of this disclosure and are intended to be within the scope of the examples discussed herein. Thus, the details of these components as set forth in the above-described examples should not limit the scope of the claims.

Further, the purpose of the Abstract is to enable the U.S. Patent and Trademark Office, and the public generally, and especially the scientists, engineers and practitioners in the art who are not familiar with patent or legal terms or phraseology, to determine quickly from a cursory inspection the nature and essence of the technical disclosure of the application. The Abstract is neither intended to define the claims of the application nor is intended to be limiting on the claims in any way.

What is claimed is:

1. A flexible cold plate assembly, comprising:
a rigid outer housing fixedly attached to a rigid header assembly having a plurality of conduits adapted for flowing fluid through said rigid header assembly, a compliant manifold fixedly attached to said rigid header assembly, a compliant connection constructed and arranged to connect said complaint manifold to a flexible microchannel matrix.

2. The flexible cold plate assembly according to claim 1, wherein said compliant manifold is constructed of an elastomeric material.

3. The flexible cold plate assembly according to claim 1, wherein said compliant manifold contains a plurality of coolant distribution channels constructed and arranged to supply and return fluid from said flexible microchannel matrix.

4. The flexible cold plate assembly according to claim 1, wherein said compliant connection is comprised of material constructed and arranged to create a hermetical seal between said flexible microchannel matrix and said manifold.

5. The flexible cold plate assembly according to claim 1, wherein said rigid header assembly is constructed of a high temperature polymer.

6. The flexible cold plate assembly according to claim 1, wherein said flexible microchannel matrix is constructed and arranged to flex between a convex and a concave position, thereby allowing for said microchannel matrix to adapt to the changes in a heat generating surface and remain attached.

7. The flexible cold plate assembly according to claim 1, wherein said flexible microchannel matrix is comprised of a high thermal conductivity metal.

8. The flexible cold plate assembly according to claim 1, wherein said flexible cold plate assembly is integrally formed.

9. A flexible cold plate assembly, comprising:
a rigid outer housing fixedly attached to a rigid header assembly having a plurality of conduits adapted for flowing fluid through said rigid header assembly, a compliant manifold fixedly attached to said rigid header assembly, a compliant connection constructed and arranged to connect said complaint manifold to a flexible microchannel matrix.

10. The flexible cold plate assembly according to claim 9, wherein said flexible microchannel matrix has at least one segment, wherein the size of each said matrix segment corresponds to size of the device that it is cooling.

11. The flexible cold plate assembly according to claim 10, wherein said at least one matrix segment is constructed and arranged to accommodate the discontinuities in the curvature of the die surface in multichip devices.

12. The flexible cold plate assembly according to claim 9, wherein said microchannel matrix is comprised of copper.

13. The flexible cold plate assembly according to claim 10, wherein said matrix segments are comprised of a plurality of embedded fluidic channels constructed and arranged for tailoring each matrix segment for pressure drop and performance.

14. The flexible cold plate assembly according to claim 9, wherein said flexible microchannel matrix microchannels are exposed to allow direct contact and heat transfer between a coolant and the surface of a heat generating device.
